(19) United States
(12) Patent Application Publication
(10) Pub. No.: US 2026/0059978 A1
(43) Pub. Date: Feb. 26, 2026

(54) DISPLAY APPARATUS HAVING A LIGHT-EMITTING DEVICE

(71) Applicant: LG Display Co., Ltd., Seoul (KR)

(72) Inventors: Jae Choul YU, Paju-si (KR); Jeong Oh KIM, Paju-si (KR); Myung Jae YOO, Paju-si (KR); Geum Young LEE, Paju-si (KR); Se Yeon JUNG, Paju-si (KR)

(73) Assignee: LG Display Co., Ltd., Seoul (KR)

(21) Appl. No.: 19/265,535

(22) Filed: Jul. 10, 2025

(30) Foreign Application Priority Data
Aug. 26, 2024 (KR) 10-2024-0114204

(51) Int. Cl. H10K 59/80

(52) U.S. Cl. CPC H10K 59/873

(57) ABSTRACT

A display apparatus including a light-emitting device is provided. The light-emitting device is be disposed between a device substrate and an encapsulation substrate, and is covered by an encapsulating adhesive layer that bonds the substrates together. The light-emitting device can be covered by the encapsulating adhesive layer. A capping insulating layer is disposed between the light-emitting device and the encapsulating adhesive layer. An oxygen barrier layer is disposed between the capping insulating layer and the encapsulating adhesive layer. The oxygen barrier layer includes a metal that quickly reacts with oxygen atoms and oxygen molecules. This configuration reduces the risk of damage to the light-emitting device caused by the penetration of external moisture and oxygen. As a result, the efficiency and the lifespan of the light-emitting device can be improved.

### CROSS-REFERENCE TO RELATED APPLICATIONS

This application claims the benefit of Korean Patent Application No. 10-2024-0114204, filed on Aug. 26, 2024, which is hereby incorporated by reference as if fully set forth herein.

### BACKGROUND

### Technical Field

The present disclosure relates to a display apparatus in which a light-emitting device is disposed between a device substrate and an encapsulation substrate.

### Description of the Related Art

Generally, a display apparatus provides an image to a user. For example, the display apparatus can include at least one light-emitting device. The light-emitting device can emit light displaying a specific color. For example, the light-emitting device can include a light-emitting unit disposed between a first electrode and a second electrode.

The light-emitting device can be disposed between a device substrate and an encapsulation substrate. The encapsulation substrate can be coupled to the device substrate by an encapsulating adhesive layer. The light-emitting device can be covered by the encapsulating adhesive layer. The encapsulation substrate can be harder than the device substrate. Thus, in the display apparatus, the damage of the light-emitting device due to external impact and moisture can be prevented.

### BRIEF SUMMARY

The present disclosure is directed to a display apparatus that substantially obviates one or more technical problems due to limitations and disadvantages of the related art. For example, the disclosure describes a display apparatus with improved protection for light-emitting devices against moisture and oxygen. The apparatus includes an oxygen barrier layer composed of a metal that reacts more readily with oxygen than the encapsulation substrate. This layer is positioned between a capping insulating layer and an encapsulating adhesive layer, with its upper surface intentionally roughened to increase adhesion and reduce the likelihood of separation under external force. The oxygen barrier layer may include distinct regions, some of which transform into transparent or color-altered metal oxides when exposed to moisture or oxygen, allowing for visual detection of penetration.

The encapsulating adhesive layer includes both moisture absorbing particles and color responsive particles that change appearance upon contact with oxygen. This combination enhances environmental resistance and enables real-time monitoring of degradation. Multiple oxygen barrier layers may be used to further reinforce the structure. Their thickness and location are designed to provide additional protection in vulnerable areas such as the bezel region. These structural features together help maintain display performance, extend operational life, and improve thermal dissipation while enabling reduced power consumption.

Various embodiments of the present disclosure provide a display apparatus capable of preventing the damage of the light-emitting device due to the penetration of the external moisture and oxygen.

Various embodiments of the present disclosure provide a display apparatus capable of easily checking the penetration of the external moisture and oxygen.

Additional advantages and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these benefits and other advantages, as embodied and broadly described herein, there is provided a display apparatus comprising a device substrate. A light-emitting device is disposed on a display area of the device substrate. A capping insulating layer is disposed on a second electrode of the light-emitting device. An encapsulating adhesive layer is disposed on the capping insulating layer. The encapsulating adhesive layer extends on a bezel area of the device substrate. An encapsulation substrate is disposed on the encapsulating adhesive layer. The encapsulation substrate overlaps the display area and the bezel area. An oxygen barrier layer is disposed between the capping insulating layer and the encapsulating adhesive layer. The oxygen barrier layer includes a metal. The oxygen barrier layer includes a first surface and a second surface. The first surface of the oxygen barrier layer is toward the encapsulating adhesive layer. The second surface of the oxygen barrier layer is opposite to the first surface of the oxygen barrier layer. An average surface roughness of the first surface is greater than an average surface roughness of the second surface.

A thermal conductivity of the encapsulation substrate can be greater than a thermal conductivity of the oxygen barrier layer.

The oxygen barrier layer can include a region in contact with the bezel area of the device substrate.

The encapsulating adhesive layer can be in contact with the bezel area of the device substrate outside the oxygen barrier layer.

The encapsulating adhesive layer can include a plurality of moisture absorbing particles and a plurality of color-changing particles. Each of the plurality of color-changing particles can include a material that reacts with oxygen atoms and oxygen molecules to change color.

A thickness of the oxygen barrier layer overlapping with the bezel area can be larger than a thickness of the oxygen barrier layer overlapping with the display area.

The oxygen barrier layer can include a first barrier region and a second barrier region. The second barrier region can have a higher transmittance than the first barrier region. The second barrier region can be disposed between the first barrier region and a side surface of the device substrate.

The second barrier region of the oxygen barrier layer can be made of metal oxide semiconductor.

In another embodiment, there is provided a display apparatus comprising a light-emitting device on an emission area of a device substrate. A light-emitting device is disposed on a device substrate. A second electrode of the light-emitting device is covered by a capping insulating layer. The light-emitting device and the capping insulating layer are covered by an encapsulating adhesive layer. An encapsulation substrate is disposed on the encapsulating adhesive layer. The encapsulation substrate includes a metal. A first oxygen barrier layer is disposed between the capping insulating layer and the encapsulating adhesive layer. The first oxygen barrier layer includes a metal that oxidizes faster than the encapsulation substrate.

A side surface of the first oxygen barrier layer disposed close to a side surface of the device substrate can be continuous with a side surface of the encapsulating adhesive layer disposed close to the side surface of the device substrate.

A second oxygen barrier layer can be disposed between the encapsulating adhesive layer and the encapsulation substrate. The second oxygen barrier layer can include a metal that oxidizes faster than the encapsulation substrate.

A thermal conductivity of the second oxygen barrier layer can be smaller than a thermal conductivity of the encapsulation substrate.

The second oxygen barrier layer can include a different material from the first oxygen barrier layer.

A thermal conductivity of the first oxygen barrier layer can be smaller than a thermal conductivity of the second oxygen barrier layer.

The first oxygen barrier layer includes a first barrier region and a second barrier region. The second barrier region can display a different color from the first barrier region. The second barrier region can be disposed between the first barrier region and a side surface of the device substrate.

### BRIEF DESCRIPTION OF THE SEVERAL VIEWS OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing a circuit of a pixel area in the display apparatus according to the embodiment of the present disclosure;

FIG. 3 is a view schematically showing a cross-section of pixel areas in the display apparatus according to the embodiment of the present disclosure;

FIG. 4 is a view taken along I-I′ of FIG. 1;

FIG. 5 is a view partially showing a plane of an oxygen barrier layer in the display apparatus according to the embodiment of the present disclosure;

FIGS. 6 and 7 are views showing the change of the oxygen barrier layer according to the penetrating of the external moisture or oxygen in the display apparatus according to the embodiment of the present disclosure; and

FIGS. 8 to 11 are views showing the display apparatus according to another embodiment of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure may be embodied in other forms and is not limited to the embodiments described below.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

It will be understood that, when a first element is referred to as being “on” a second element, although the first element may be disposed on the second element so as to come into contact with the second element, a third element may be interposed between the first element and the second element.

Here, terms such as, for example, “first” and “second” may be used to distinguish any one element with another element. However, the first element and the second element may be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” may include that two components are “connected” or “coupled” through one or more other components located between the two components.

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

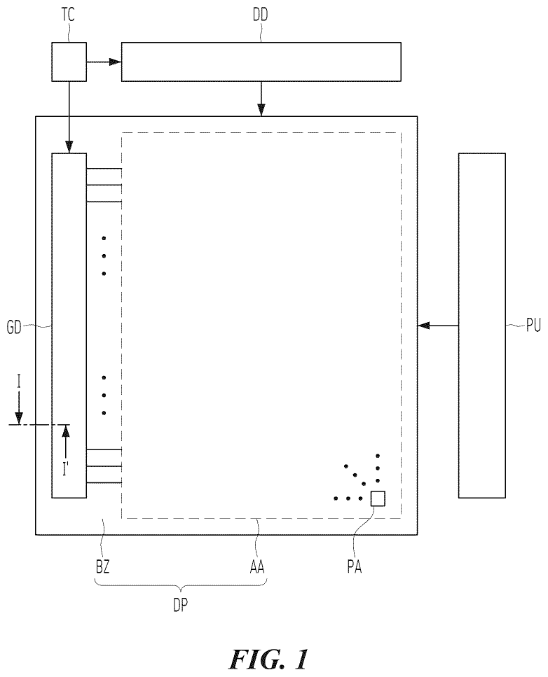

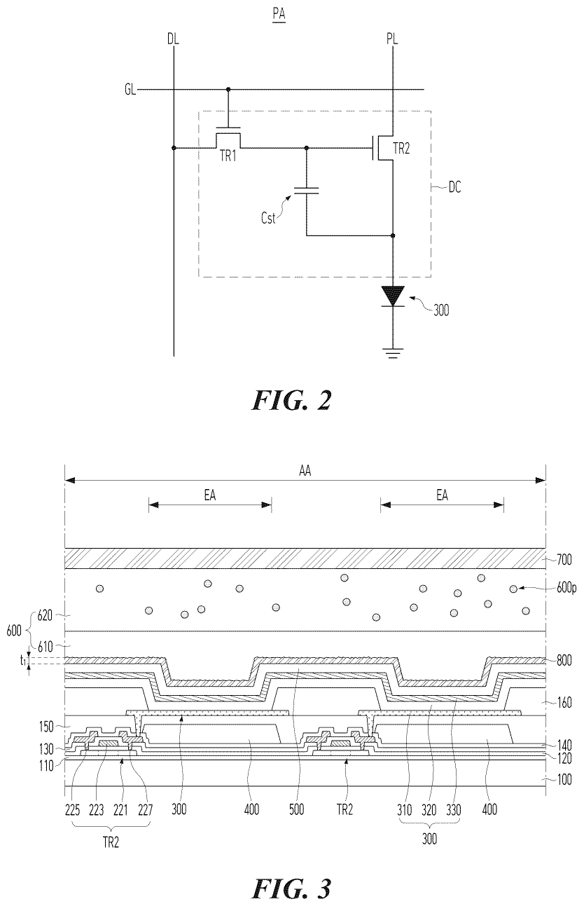

FIG. 1 is a view schematically showing a display apparatus according to an embodiment of the present disclosure. FIG. 2 is a view showing a circuit of a pixel area in the display apparatus according to the embodiment of the present disclosure. FIG. 3 is a view schematically showing a cross-section of pixel areas in the display apparatus according to the embodiment of the present disclosure.

Referring to FIGS. 1 to 3, the display apparatus according to the embodiment of the present disclosure can include a display panel DP. The display panel DP can generate an image provided to a user. For example, the display panel DP can include a plurality of pixel areas PA.

Various signals can be applied in each pixel area PA through signal wirings GL, DL and PL. For example, the signal wirings GL, DL and PL can include gate lines GL applying a gate signal, data lines DL applying a data signal, and power voltage supply lines PL supplying a power voltage.

Each of the pixel areas PA can realize a specific color. For example, a light-emitting device 300 can be disposed in each pixel area PA. The light-emitting device 300 can emit light displaying a specific color. For example, the light-emitting device 300 can include a first electrode 310, a light-emitting unit 320 and a second electrode 330, which are sequentially stacked.

The first electrode 310 and the second electrode 330 can include a conductive material. The second electrode 330 can include a different material from the first electrode 310. For example, the reflectance of the second electrode 330 can be larger than the reflectance of the first electrode 310. The first electrode 310 can have a higher transmittance than the second electrode 330. For example, the first electrode 310 can be a transparent electrode made of a transparent conductive material, such as ITO and IZO, and the second electrode 330 can be a reflective electrode including a metal, such as aluminum (Al) and silver (Ag). The second electrode 330 can have a work-function smaller than the first electrode 310. For example, the first electrode 310 can function as an anode electrode, and the second electrode 330 can function as a cathode electrode.

The light-emitting unit 320 can generate light having luminance corresponding to a voltage difference between the first electrode 310 and the second electrode 330. For example, the light-emitting unit 320 can include at least one emission material layer (EML). The emission material layer can include an organic emission material, an inorganic emission material, or a hybrid emission material. For example, the display apparatus according to the embodiment of the present disclosure can be an organic light-emitting display apparatus including an organic emission material.

The light-emitting unit 320 can include at least one functional layer. The functional layer can be disposed between the first electrode 310 and the emission material layer and/or the emission material layer and the second electrode 330. Holes and electrons can be smoothly moved by the functional layer. For example, the functional layer can be one of a hole injection layer (HIL), a hole transport layer (HTL), an electron transport layer (ETL) and an electron injection layer (EIL). Thus, in the display apparatus according to the embodiment of the present disclosure, the efficiency of the light-emitting unit 320 can be improved.

A driving circuit DC can be disposed in each pixel area PA to control the operation of the light-emitting device 300. The driving circuit DC of each pixel area PA can be electrically connected to the light-emitting device 300 of the corresponding pixel area PA. The driving circuit DC of each pixel area PA can be electrically connected to the signal wirings GL, DL and PL. For example, the driving circuit DC of each pixel area PA can be electrically connected to one of the gate lines GL, one of the data lines DL, and one of the power voltage supply lines PL. The driving circuit DC of each pixel area PA can supply a driving current corresponding to the data signal to the light-emitting device 300 of the corresponding pixel area PA according to the gate signal for one frame. For example, the driving circuit DC of each pixel area PA can include a first thin film transistor TR1, a second thin film transistor TR2 and a storage capacitor Cst.

The first thin film transistor TR1 of each pixel area PA can transmit the data signal to the second thin film transistor TR2 of the corresponding pixel area PA according to the gate signal. For example, the first thin film transistor TR1 of each pixel area PA can function as a switching thin film transistor. The first thin film transistor TR1 of each pixel area PA can include a first semiconductor pattern, a first gate electrode, a first drain electrode and a first source electrode. For example, the first gate electrode of each pixel area PA can be electrically connected to the corresponding gate lines GL, and the first drain electrode of each pixel area PA can be electrically connected to the corresponding date lines DL.

The second thin film transistor TR2 of each pixel area PA can generate the driving current corresponding to the data signal. For example, the second thin film transistor TR2 of each pixel area PA can function as a driving thin film transistor. The second thin film transistor TR2 of each pixel area PA can include a second semiconductor pattern 221, a second gate electrode 223, a second drain electrode 225 and a second source electrode 227. For example, the second gate electrode 223 of each pixel area PA can be electrically connected to the first source electrode of the corresponding pixel area PA, and the second drain electrode 225 of each pixel area PA can be electrically connected to the corresponding power voltage supply lines PL. The light-emitting device 300 of each pixel area PA can be electrically connected to the second source electrode 227 of the corresponding pixel area PA.

The second semiconductor pattern 221 can include a semiconductor material. For example, the second semiconductor pattern 221 can include amorphous silicon (a-Si), polycrystalline silicon (poly-Si) or an oxide semiconductor, such as IGZO. The second semiconductor pattern 221 can include a drain region, a channel region and a source region. The channel region can be disposed between the drain region and the source region. The drain region and the source region can have a smaller resistance than the channel region. For example, the drain region and the source region can include a conductive region of an oxide semiconductor. The channel region can be a region of an oxide semiconductor, which is not conductorized.

The second semiconductor pattern 221 can include a same material as the first semiconductor pattern. The second semiconductor pattern 221 can be disposed on a same layer as the first semiconductor pattern. The second semiconductor pattern 221 can be formed by a same process as the first semiconductor pattern. For example, the second semiconductor pattern 221 can be formed simultaneously with the first semiconductor pattern.

The second gate electrode 223 can be disposed on a portion of the second semiconductor pattern 221. For example, the second gate electrode 223 can overlap the channel region of the second semiconductor pattern 221. The drain region and the source region of the second semiconductor pattern 221 can be disposed outside the second gate electrode 223. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be spaced apart from the second semiconductor pattern 221. The second gate electrode 223 can be insulated from the second semiconductor pattern 221. For example, the channel region of the second semiconductor pattern 221 can have an electrical conductivity corresponding to a voltage of a signal applied to the second gate electrode 223.

The second gate electrode 223 can include a same material as the first gate electrode. The second gate electrode 223 can be disposed on a same layer as the first gate electrode. The second gate electrode 223 can be formed by a same process as the first gate electrode. For example, the second gate electrode 223 can be formed simultaneously with the first gate electrode.

The second drain electrode 225 can be electrically connected to the drain region of the second semiconductor pattern 221. The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can include a different material from the second gate electrode 223. The second drain electrode 225 can be insulated from the second gate electrode 223. For example, the second drain electrode 225 can be disposed on a different layer from the second gate electrode 223.

The second drain electrode 225 can include a same material as the first drain electrode. The second drain electrode 225 can be disposed on a same layer as the first drain electrode. The second drain electrode 225 can be formed by a same process as the first drain electrode. For example, the second drain electrode 225 can be formed simultaneously with the first drain electrode.

The second source electrode 227 can be electrically connected to the source region of the second semiconductor pattern 221. The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can include a different material from the second gate electrode 223. The second source electrode 227 can be insulated from the second gate electrode 223. For example, the second source electrode 227 can be disposed on a different layer from the second gate electrode 223. The second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be spaced apart from the second drain electrode 225.

The second source electrode 227 can include a same material as the first source electrode. The second source electrode 227 can be disposed on a same layer as the first source electrode. The second source electrode 227 can be formed by a same process as the first source electrode. For example, the second source electrode 227 can be formed simultaneously with the first source electrode. Thus, in the display apparatus according to the embodiment of the present disclosure, the process efficiency can be improved.

The storage capacitor Cst of each pixel area PA can maintain a signal applied to the second gate electrode 223 of the corresponding pixel area PA for one frame. For example, the storage capacitor Cst of each pixel area PA can be electrically connected to the second gate electrode 223 and the second source electrode 227 of the corresponding pixel area PA. The storage capacitor Cst of each pixel area PA can be formed using a process of forming the first thin film transistor TR1 and the second thin film transistor TR2 of the corresponding pixel area PA. The storage capacitor Cst of each pixel area PA can have a stacked structure of capacitor electrodes. For example, the storage capacitor Cst of each pixel area PA can include a first capacitor electrode disposed on a same layer as the second gate electrode 233 of the corresponding pixel area PA, and a second capacitor electrode disposed on a same layer as the second source electrode 227 of the corresponding pixel area PA. Thus, in the display apparatus according to the embodiment of the present disclosure, a process of forming the driving circuit DC of each pixel area PA can be simplified.

The driving circuit DC and the light-emitting device 300 of each pixel area PA can be disposed on a device substrate 100. For example, the first thin film transistor TR1, the second thin film transistor TR2 and the storage capacitor Cst of each pixel area PA can be supported by the device substrate 100. The device substrate 100 can include an insulating material. The device substrate 100 can include a transparent material. For example, the device substrate 100 can include glass or plastic. A plurality of insulating layers 110, 120, 130, 140, 150 and 160 for preventing unnecessary electrical connection can be disposed on the device substrate 100. For example, a buffer insulating layer 110, a gate insulating layer 120, an interlayer insulating layer 130, a device passivation layer 140, a planarization layer 150 and a bank insulating layer 160 can be stacked on the device substrate 100.

The buffer insulating layer 110 can be disposed close to the device substrate 100. The buffer insulating layer 110 can prevent pollution due to the device substrate 100 in a process of forming the driving circuit DC of each pixel area PA. For example, an upper surface of the device substrate 100 toward the driving circuit DC of each pixel area PA can be covered by the buffer insulating layer 110. The first thin film transistor TR1, the second thin film transistor TR2 and the storage capacitor Cst of each pixel area PA can be disposed on the buffer insulating layer 110. The buffer insulating layer 110 can include an insulating material. For example, the buffer insulating layer 110 can be an inorganic insulating layer made of an inorganic insulating material, such as silicon oxide (SiOx) and silicon nitride (SiNx). The buffer insulating layer 110 can have a multi-layer structure. For example, the buffer insulating layer 110 can have a stacked structure of an inorganic insulating layer made of silicon oxide (SiOx) and an inorganic insulating layer made of silicon nitride (SiNx).

The gate insulating layer 120 can be disposed on the buffer insulating layer 110. The second gate electrode 223 of each pixel area PA can be insulated from the second semiconductor pattern 221 of the corresponding pixel area PA by the gate insulating layer 120. For example, the gate insulating layer 120 can cover the first semiconductor pattern and the second semiconductor pattern 221 of each pixel area PA. The first gate electrode and the second gate electrode 223 of each pixel area PA can be disposed on the gate insulating layer 120. The gate insulating layer 120 can include an insulating material. For example, the gate insulating layer 120 can be an inorganic insulating layer made of an inorganic insulating material.

The interlayer insulating layer 130 can be disposed on the gate insulating layer 120. The second drain electrode 225 and the second source electrode 227 of each pixel area PA may be insulated from the second gate electrode 223 of the corresponding pixel area PA by the interlayer insulating layer 130. For example, the interlayer insulating layer 130 can cover the first gate electrode and the second gate electrode 223 of each pixel area PA. The first drain electrode, the first source electrode, the second drain electrode 225 and the second source electrode 227 of each pixel area PA can be disposed on the interlayer insulating layer 130. The interlayer insulating layer 130 can include an insulating material. For example, the interlayer insulating layer 130 can be an inorganic insulating layer made of an inorganic insulating material.

The device passivation layer 140 can be disposed on the interlayer insulating layer 130. The device passivation layer 140 can prevent the damage of the driving circuit DC in each pixel area PA due to external impact and moisture. For example, the first drain electrode, the first source electrode, the second drain electrode 225 and the second source electrode 227 of each pixel area PA can be covered by the device passivation layer 140. The device passivation layer 140 can include an insulating material. For example, the device passivation layer 140 can be an inorganic insulating layer made of an inorganic insulating material.

The planarization layer 150 can be disposed on the device passivation layer 140. The planarization layer 150 can remove a thickness difference due to the driving circuit DC of each pixel area PA. For example, an upper surface of the planarization layer 150 opposite to the device substrate 100 can be flat. The upper surface of the planarization layer 150 can be parallel to the upper surface of the device substrate 100. The planarization layer 150 can include an insulating material. The planarization layer 150 can include a different material from the device passivation layer 140. The planarization layer 150 can include a material having a relatively high fluidity. For example, the planarization layer 150 can be an organic insulating layer made of an organic insulating material.

The light-emitting device 300 of each pixel area PA may be disposed on the planarization layer 150. For example, the first electrode 310, the light-emitting unit 320 and the second electrode 330 of each pixel area PA can be sequentially stacked on the upper surface of the planarization layer 150 in the corresponding pixel area PA. The light-emitting device 300 of each pixel area PA can be controlled independently from the light-emitting device 300 of adjacent pixel area PA. For example, the first electrode 310 of each pixel area PA can be insulated from the first electrode 310 of adjacent pixel area PA by the bank insulating layer 160. The bank insulating layer 160 can include an insulating material. For example, the bank insulating layer 160 can be an organic insulating layer made of an organic insulating material. The bank insulating layer 160 can include a different material from the planarization layer 150.

The bank insulating layer 160 can be disposed on the planarization layer 150. The bank insulating layer 160 can partially expose the first electrode 310 of each pixel area PA. For example, an edge of the first electrode 310 in each pixel area PA can be covered by the bank insulating layer 160. The light-emitting unit 320 and the second electrode 330 of each pixel area PA can be stacked on a central portion of the corresponding first electrode 310 exposed by the bank insulating layer 160. Thus, in the display apparatus according to the embodiment of the present disclosure, an emission area EA can be defined in each pixel area PA by the bank insulating layer 160. For example, light can't be generated and emitted in a portion of each pixel area PA overlapping with the bank insulating layer 160. The first electrode 310 of each pixel area PA can be electrically connected to the driving circuit DC of the corresponding pixel area PA outside the emission area EA defined in the corresponding pixel area PA. Therefore, in the display apparatus according to the embodiment of the present disclosure, the luminance deviation depending on the generation location of the light emitted from the light-emitting device 300 of each pixel area PA can be prevented.

The light generated by the light-emitting unit 320 of each pixel area PA can be emitted outside through the first electrode 310 of the corresponding pixel area PA and the device substrate 100. The driving circuit DC of each pixel area PA can be disposed outside the emission area EA defined in the corresponding pixel area PA. For example, the first thin film transistor TR1, the second thin film transistor TR2 and the storage capacitor Cst of each pixel area PA can't overlap the emission area EA of the corresponding pixel area PA. Thus, in the display apparatus according to the embodiment of the present disclosure, the light emitted from the light-emitting device 300 of each pixel area PA can't be blocked by the driving circuit DC of the corresponding pixel area PA.

Therefore, in the display apparatus according to the embodiment of the present disclosure, the light extraction efficiency of each pixel area PA can be improved. And, in the display apparatus according to the embodiment of the present disclosure, the efficiency of the light-emitting device 300 on each pixel area PA can be improved.

A signal applied to the second electrode 330 of each pixel area PA can be a same as a signal applied to the second electrode 330 of adjacent pixel area PA. For example, the second electrode 330 of each pixel area PA can be electrically connected to the second electrode 330 of adjacent pixel area PA. The second electrode 330 of each pixel area PA can include a same material as the second electrode 330 of adjacent pixel area PA. The second electrode 330 of each pixel area PA can be formed by a same process as the second electrode of adjacent pixel area PA. For example, the second electrode 330 of each pixel area PA can be formed simultaneously with the second electrode 330 of adjacent pixel area PA. The second electrode 330 of each pixel area PA can be in direct contact with the second electrode 330 of adjacent pixel area PA. Thus, in the display apparatus according to the embodiment of the present disclosure, a process of forming the second electrode 330 in each pixel area PA may be simplified.

The light emitted from the light-emitting device 300 of each pixel area PA can be display a same color as the light emitted from the light-emitting device 300 of adjacent pixel area PA. For example, the light-emitting device 300 of each pixel area PA can emit white light. The light-emitting unit 320 of each pixel area PA can have a stacked structure same as the light-emitting unit 320 of adjacent pixel area PA. The light-emitting unit 320 of each pixel area PA can be formed by a same process of the light-emitting unit 320 of adjacent pixel area PA. For example, the light-emitting unit 320 of each pixel area PA can be formed simultaneously with the light-emitting unit 320 of adjacent pixel area PA. Thus, in the display apparatus according to the embodiment of the present disclosure, a process of forming the light-emitting unit 320 in each pixel area PA may be simplified.

The color realized by each pixel area PA can be different from the color realized by adjacent pixel area PA. For example, a color filter 400 can be disposed on each pixel area PA. The color filter 400 of each pixel area PA can realize a specific color by using the light emitted from the light-emitting device 300 of the corresponding pixel area PA. The color filter 400 of each pixel area PA can include a different material from the color filter 400 of adjacent pixel area PA. The color filter 400 of each pixel area PA can be disposed on a path of the light emitted from the light-emitting device 300 of the corresponding pixel area PA. For example, the color filter 400 of each pixel area PA can be disposed between the device passivation layer 140 and the planarization layer 150. A thickness difference due to the color filter 400 of each pixel area PA can be removed by the planarization layer 150. Thus, in the display apparatus according to the embodiment of the present disclosure, the image provided to the user can include various colors.

A capping insulating layer 500 can be disposed on the light-emitting device 300 of each pixel area PA. The capping insulating layer 500 can prevent the damage of the light-emitting device 300 on each pixel area PA due to the external moisture. For example, the second electrode 330 of each pixel area PA can be covered by the capping insulating layer 500. The capping insulating layer 500 can include an insulating material. For example, the capping insulating layer 500 can be an inorganic insulating layer made of an inorganic insulating material.

An encapsulating adhesive layer 600 and an encapsulation substrate 700 can be disposed on the capping insulating layer 500. The encapsulation substrate 700 can be coupled to the device substrate 100 in which the light-emitting devices 300 are formed by the encapsulating adhesive layer 600. The encapsulating adhesive layer 600 can include an adhesive material. For example, the encapsulating adhesive layer 600 can include a curable resin, such as epoxy and olefin. The encapsulating adhesive layer 600 can prevent the damage of the light-emitting device 300 on each pixel area PA due to the penetration of the external moisture. For example, the encapsulating adhesive layer 600 can include a plurality of moisture absorbing particles 600p. Each of the moisture absorbing particles 600p can include a material capable of capturing moisture. For example, each of the moisture absorbing particles 600p can include at least one of a metal powder, a metal oxide and a metal salt.

The encapsulating adhesive layer 600 can have a multi-layer structure. For example, the encapsulating adhesive layer 600 can have a stacked structure of a first encapsulating layer 610 and a second encapsulating layer 620. The first encapsulating layer 610 can be disposed between the capping insulating layer 500 and the second encapsulating layer 620. A lower surface of the second encapsulating layer 620 toward the device substrate 100 can be in direct contact with an upper surface of the first encapsulating layer 610 toward the encapsulation substrate 700. The plurality of moisture absorbing particles 600p can be dispersed in the second encapsulating layer 620. Each of the moisture absorbing particles 600p can be expanded by capturing moisture. Thus, in the display apparatus according to the embodiment of the present disclosure, the stress applied to the light-emitting device 300 of each pixel area PA due to the expansion of each moisture absorbing particle 600p can be mitigated by the first encapsulating layer 610. The first encapsulating layer 610 can include a different material from the second encapsulating layer 620. Therefore, in the display apparatus according to the embodiment of the present disclosure, the damage of the light-emitting device 300 on each pixel area PA due to the penetration of the external moisture can be effectively prevented.

The encapsulation substrate 700 can mitigate the external impact applied toward the light-emitting device 300 of each pixel area PA. For example, the encapsulation substrate 700 can include a material harder than the device substrate 100. The encapsulation substrate 700 can include a material having a higher thermal conductivity than the device substrate 100. For example, the encapsulation substrate 700 can include a metal, such as aluminum (Al), iron (Fe) and nickel (Ni). Thus, in the display apparatus according to the embodiment of the present disclosure, the heat generated by the operation of the driving circuit DC and the light-emitting device 300 in each pixel area PA can be emitted outside through the encapsulation substrate 700. Therefore, in the display apparatus according to the embodiment of the present disclosure, the deterioration of the light-emitting device 300 in each pixel area PA can be prevented.

An oxygen barrier layer 800 can be disposed between the capping insulating layer 500 and the first encapsulating layer 610. The oxygen barrier layer 800 can include a material that is highly reactive with oxygen atoms and oxygen molecules. For example, the oxygen barrier layer 800 can include a metal. In general, the moisture can be made of hydrogen atoms and oxygen molecules. Thus, in the display apparatus according to the embodiment of the present disclosure, the external moisture and oxygen penetrating through the encapsulating adhesive layer 600 can be reacted with the oxygen barrier layer 800. That is, in the display apparatus according to the embodiment of the present disclosure, the oxygen barrier layer 800 can be oxidized by the moisture and oxygen that are not captured by the plurality of moisture absorbing particles 600p. Therefore, in the display apparatus according to the embodiment of the present disclosure, the damage of the light-emitting device 300 on each pixel area PA due to the penetration of the external moisture and oxygen can be prevented.

The oxygen barrier layer 800 can include a different material from the encapsulation substrate 700. A thermal conductivity of the oxygen barrier layer 800 can be lower than a thermal conductivity of the encapsulation substrate 700. Thus, in the display apparatus according to the embodiment of the present disclosure, the heat generated by the operation of the driving circuit DC and the light-emitting device 300 in each pixel area PA can be quickly moved to the encapsulation substrate 700 through the oxygen barrier layer 800. Therefore, in the display apparatus according to the embodiment of the present disclosure, the heat dissipation efficiency can be improved. And, in the display apparatus according to the embodiment of the present disclosure, the deterioration of the light-emitting device 300 in each pixel area PA can be effectively prevented.

The oxygen barrier layer 800 can include a metal that oxidizes faster than the encapsulation substrate 700. For example, the oxygen barrier layer 800 can include at least one of indium (In), zinc (Zn), gallium (Ga) and titanium (Ti). Thus, in the display apparatus according to the embodiment of the present disclosure, the external moisture and oxygen penetrated through the encapsulating adhesive layer 600 can move toward the oxygen barrier layer 800 rather than the encapsulation substrate 700. That is, in the display apparatus according to the embodiment of the present disclosure, the oxidization of the encapsulation substrate 700 due to the penetration of the external moisture and oxygen can be prevented. Therefore, in the display apparatus according to the embodiment of the present disclosure, the decrease in the heat dissipation efficiency due to the corrosion of the encapsulation substrate 700 can be prevented.

Accordingly, the display apparatus according to the embodiment of the present disclosure can comprise the capping insulating layer 500 disposed on the light-emitting device 300 of each pixel area PA, the encapsulating adhesive layer 600 disposed on the capping insulating layer 500, the encapsulation substrate 700 disposed on the encapsulating adhesive layer 600, and the oxygen barrier layer 800 disposed between the capping insulating layer 500 and the encapsulating adhesive layer 600, wherein the oxygen barrier layer 800 can include a metal that oxidizes faster than the encapsulation substrate 600. Thus, in the display apparatus according to the embodiment of the present disclosure, the damage of the light-emitting device 300 on each pixel area PA due to the penetration of the external moisture and oxygen can be prevented. And, in the display apparatus according to the embodiment of the present disclosure, the decrease in the heat dissipation efficiency due to the penetration of the external moisture and oxygen can be prevented. Therefore, in the display apparatus according to the embodiment of the present disclosure, the efficiency and the lifespan of the light-emitting device 300 on each pixel area PA can be improved. That is, in the display apparatus according to the embodiment of the present disclosure, the low power operation is possible and the power consumption can be reduced.

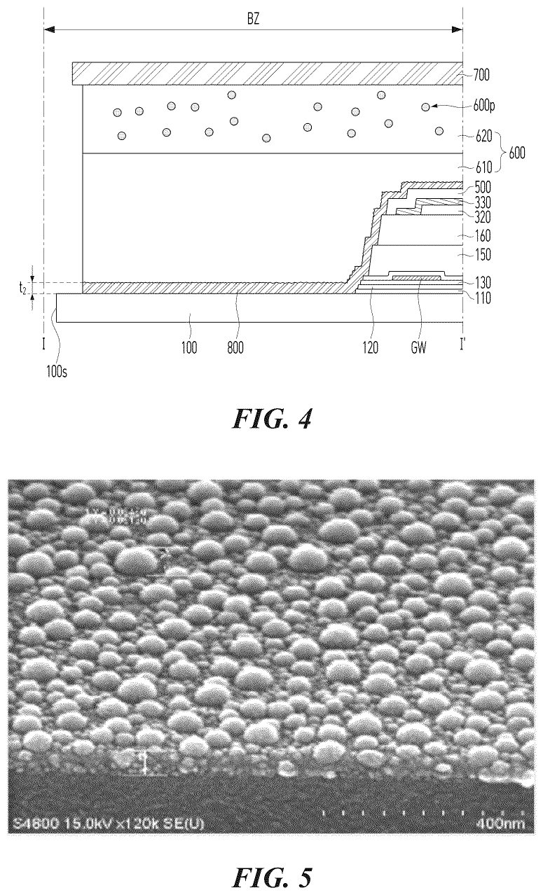

FIG. 4 is a view taken along I-I′ of FIG. 1. FIG. 5 is a view partially showing a plane of the oxygen barrier layer 800 in the display apparatus according to the embodiment of the present disclosure.

Referring to FIGS. 1 and 3 to 5, in the display apparatus according to the embodiment of the present disclosure, the display panel DP can include the display area AA (i.e., an active area AA) in which the pixel areas PA are disposed, and a bezel area BZ disposed outside the active area AA. For example, the active area AA can be surrounded by the bezel area BZ. A gate driver GD electrically connected to the gate lines GL, a data driver DD electrically connected to the data lines DL, a power unit PU electrically connected to the power voltage supply lines PL, and a timing controller TC controlling the gate driver GD and the data driver DD can be disposed outside the active area AA. For example, each of the signal wirings GL, DL and PL can extend on the bezel area BZ. At least one of the gate driver GD, the data driver DD, the power unit PU and the timing controller TC can be disposed on the bezel area BZ. For example, the display apparatus according to the embodiment of the present disclosure can be a GIP (Gate In Panel) type display apparatus in which the gate driver GD is formed on the bezel area BZ.

The buffer insulating layer 110, the gate insulating layer 120, the interlayer insulating layer 130, the device passivation layer 140, the planarization layer 150, the bank insulating layer 160 and the capping insulating layer 500 can extend onto the bezel area BZ. Wirings constituting the gate driver GD can be formed using a process of forming the driving circuit DC of each pixel area PA. For example, some of the wiring GW constituting the gate driver GD can be disposed between the gate insulating layer 120 and the interlayer insulating layer 130 of the bezel area BZ.

Each of the buffer insulating layer 110, the gate insulating layer 120, the interlayer insulating layer 130, the device passivation layer 140, the planarization layer 150, the bank insulating layer 160 and the capping insulating layer 500 can include an end portion disposed on the bezel area BZ. The encapsulating adhesive layer 600, the encapsulation substrate 700 and the oxygen barrier layer 800 can extend onto the bezel area BZ. For example, an end portion of the buffer insulating layer 110, an end portion of the gate insulating layer 120, an end portion of the interlayer insulating layer 130, an end portion of the device passivation layer 140, an end portion of the planarization layer 150, an end portion of the bank insulating layer 160 and an end portion of the capping insulating layer 500, which are disposed on the bezel area BZ can be covered by the oxygen barrier layer 800. Thus, in the display apparatus according to the embodiment of the present disclosure, the penetration of the external moisture and oxygen through boundaries between the buffer insulating layer 110, the gate insulating layer 120, the interlayer insulating layer 130, the device passivation layer 140, the planarization layer 150 and the bank insulating layer 160 can be blocked by the oxygen barrier layer 800.

The oxygen barrier layer 800 can extend along the bezel area BZ of the device substrate 100 and the first encapsulating layer 610. The oxygen barrier layer 800 can include a region in direct contact with the bezel area BZ of the device substrate 100. For example, a side surface of the oxygen barrier layer 800 disposed close to a side surface 100s of the device substrate 100 can be continuous with a side surface of the encapsulating adhesive layer 600 disposed close to the side surface 100s of the device substrate 100. Thus, in the display apparatus according to the embodiment of the present disclosure, the penetration of the external moisture and oxygen through the encapsulating adhesive layer 600 can be effectively blocked.

The oxygen barrier layer 800 overlapping with the bezel area BZ outside the buffer insulating layer 110 can be a thicker than the oxygen barrier layer 800 overlapping with the buffer insulating layer 110. For example, a second thickness t2 of the oxygen barrier layer 800 overlapping with the bezel area BZ can be a larger than a first thickness t1 of the oxygen barrier layer 800 overlapping with the display area AA. Thus, in the display apparatus according to the embodiment of the present disclosure, the amount of moisture and oxygen captured by the oxygen barrier layer 800 on the bezel area BZ can be larger than the amount of moisture and oxygen captured by the oxygen barrier layer 800 on the display area AA. Therefore, in the display apparatus according to the embodiment of the present disclosure, the influence of moisture and oxygen captured by the oxygen barrier layer 800 on the light-emitting device 300 of each pixel area PA can be minimized.

The oxygen barrier layer 800 can be formed by a deoxidization process using hydrogen plasma. For example, a process of forming the oxygen barrier layer 800 can include a step of forming a metal oxide layer, such as ITO, IZO and IGZO on the entire surface of the device substrate 100 in which the capping insulating layer 500 is formed, and a step of deoxidizing the metal oxide layer using hydrogen plasma. Thus, in the display apparatus according to the embodiment of the present disclosure, an upper surface of the oxygen barrier layer 800 toward the encapsulating adhesive layer 600 can become rough, as shown in FIG. 5. For example, the upper surface of the oxygen barrier layer 800 can have an average surface roughness greater than a lower surface of the oxygen barrier layer 800 toward the device substrate 100. That is, in the display apparatus according to the embodiment of the present disclosure, a contact area of the oxygen barrier layer 800 and the first encapsulating layer 610 can be increased. Therefore, in the display apparatus according to the embodiment of the present disclosure, an adhesive force between the oxygen barrier layer 800 and the encapsulating adhesive layer 600 can be increased. And, in the display apparatus according to the embodiment of the present disclosure, the interfacial separation between the oxygen barrier layer 800 and the encapsulating adhesive layer 600 due to the external impact can be prevented. Further, in the display apparatus according to the embodiment of the present disclosure, the external moisture and oxygen penetrating through the encapsulating adhesive layer 600 can be quickly captured by the oxygen barrier layer 800.

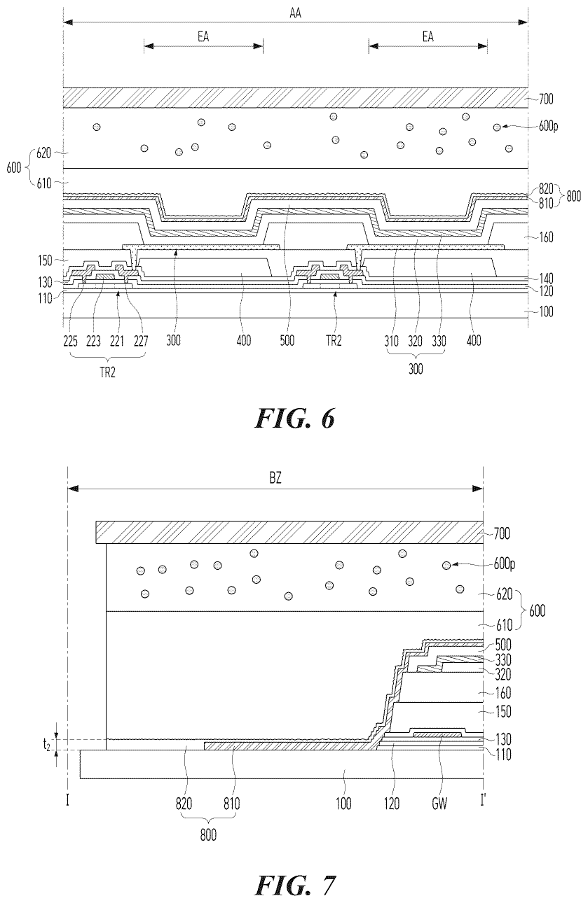

In the display apparatus according to the embodiment of the present disclosure, a portion of the oxygen barrier layer 800 can be oxidized by the penetration of the external moisture or oxygen. A portion of the oxygen barrier layer 800 oxidized by moisture or oxygen can have a different characteristics from a portion of the oxygen barrier layer 800 that is not oxidized by moisture and oxygen. For example, in the display apparatus according to the embodiment of the present disclosure, the oxygen barrier layer 800 on the display area AA can include a first barrier region 810 and a second barrier region 820 disposed on the first barrier region 810 due to the penetration of the external moisture or oxygen, as shown in FIG. 6. The second barrier region 820 can be in direct contact with an upper surface of the first barrier region 810 toward the encapsulation substrate 700. For example, the first barrier region 810 can be disposed between the capping insulating layer 500 and the second barrier region 820.

The first barrier region 810 can be a region that is not oxidized by moisture and oxygen, and the second barrier region 820 can be a region oxidized by the penetration of the external moisture or oxygen. For example, when the first barrier region 810 can include indium (In), gallium (Ga) and zinc (Zn), the second barrier region 820 can be made of a metal oxide semiconductor, such as IGZO. When the first barrier region 810 can include indium (In) and titanium (Ti), the second barrier region 820 can be made of a transparent conductive metal oxide, such as ITO. Thus, in the display apparatus according to the embodiment of the present disclosure, the second barrier region 820 can have a higher transmittance than the first barrier region 810. And, in the display apparatus according to the embodiment of the present disclosure, the second barrier region 820 can display a different color from the first barrier region 810. Therefore, in the display apparatus according to the embodiment of the present disclosure, the amount of moisture and oxygen penetrated in the display area AA can be easily checked by the transmittance and/or the change in color of the oxygen barrier layer 800.

In the display apparatus according to the embodiment of the present disclosure, a portion of the second barrier region 820 disposed close to the side surface of the device substrate 100 can be a relative thicker than another portion of the second barrier region 820, as shown in FIG. 7.

For example, a portion of the oxygen barrier layer 800 disposed close to the side surface of the device substrate 100 can be made of only the second barrier region 820. An end portion of the first barrier region 810 on the bezel area BZ can be surrounded by the device substrate 100 and the second barrier region 820. For example, the second barrier region 820 on the bezel area BZ can be in direct contact with the upper surface of the device substrate 100 outside the first barrier region 810. A portion of the second barrier region 820 can be disposed between the first barrier region 810 and the side surface of the device substrate 100 in a direction parallel to the upper surface of the device substrate 100. Thus, in the display apparatus according to the embodiment of the present disclosure, the penetration location of the external moisture and oxygen can be easily checked by the second barrier region 820 formed on the bezel area BZ. And, in the display apparatus according to the embodiment of the present disclosure, the degree of the penetration of the external moisture and oxygen can be easily checked by the horizontal length and/or the area of the second barrier region 820. That is, in the display apparatus according to the embodiment of the present disclosure, the penetration path of moisture and oxygen can be identified, without the damage of the light-emitting device 300 on each pixel area PA. Therefore, in the display apparatus according to the embodiment of the present disclosure, a region in which moisture and/or oxygen is penetrated can be quickly repaired without the damage of the light-emitting devices 300. For example, in the display apparatus according to the embodiment of the present disclosure, the encapsulating adhesive layer 600 can be quickly replaced, before moisture and oxygen penetrate into the display area AA.

The display apparatus according to the embodiment of the present disclosure is described that the driving circuit DC of each pixel area PA consists of the first thin film transistor TR1, the second thin film transistor TR2 and the storage capacitor Cst. However, in the display apparatus according to another embodiment of the present disclosure, the driving circuit DC of each pixel area PA can include a driving thin film transistor and at least one switching thin film transistor. For example, in the display apparatus according to another embodiment of the present disclosure, the driving circuit DC of each pixel area PA can further include a third thin film transistor to initialize the storage capacitor Cst of the corresponding pixel area PA according to the gate signal. The third thin film transistor of each pixel area PA can include a third semiconductor pattern, a third gate electrode, a third drain electrode and a third source electrode. The third semiconductor pattern of each pixel area PA can include a semiconductor pattern. The third gate electrode of each pixel area PA can be electrically connected to one of the gate lines GL. The third drain electrode of each pixel area PA can be electrically connected to an initial line applying an initial signal. The third source electrode of each pixel area PA can be electrically connected to the storage capacitor Cst of the corresponding pixel area PA. Thus, in the display apparatus according to another embodiment of the present disclosure, the degree of freedom in the configuration of the driving circuit DC in each pixel area PA can be improved.

In the display apparatus according to the embodiment of the present disclosure, the location and the electric connection of the first drain electrode, the first source electrode, the second drain electrodes 225 and the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

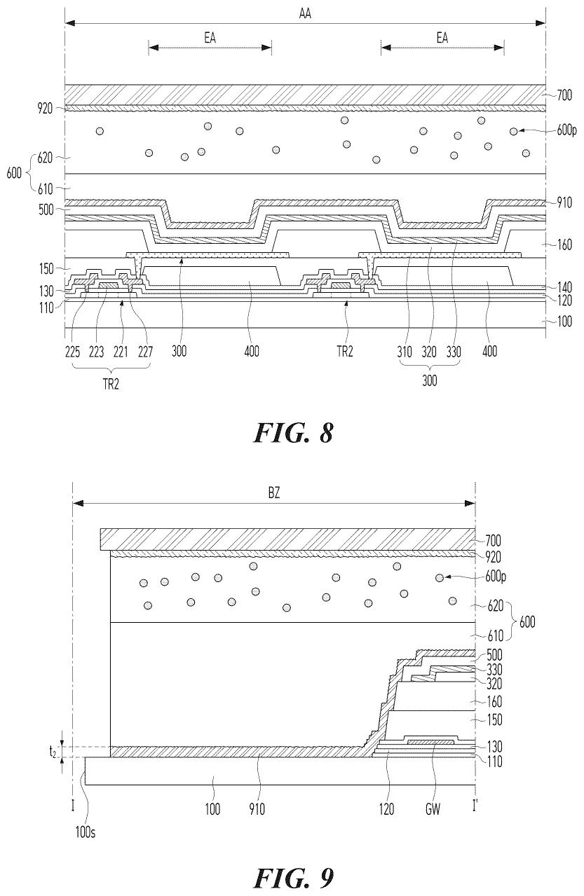

The display apparatus according to the embodiment of the present disclosure is described that the oxygen barrier layer 800 is disposed only between the capping insulating layer 500 and the encapsulating adhesive layer 600. However, the display apparatus according to another embodiment of the present disclosure can include a plurality of oxygen barrier layer 800. For example, in the display apparatus according to another embodiment of the present disclosure, a first oxygen barrier layer 910 can be disposed between the capping insulating layer 500 and the first encapsulating layer 610, and a second oxygen barrier layer 920 can be disposed between the second encapsulating layer 620 and the encapsulation substrate 700, as shown in FIGS. 8 and 9. The first oxygen barrier layer 910 and the second oxygen barrier layer 920 can include a metal that oxidizes faster than the encapsulation substrate 700. Thus, in the display apparatus according to another embodiment of the present disclosure, moisture and oxygen that is not captured by the plurality of moisture absorbing particles 600p can react with the first oxygen barrier layer 910 or the second oxygen barrier layer 920. Therefore, in the display apparatus according to the embodiment of the present disclosure, the damage of the light-emitting device 300 on each pixel area PA due to the penetration of the external moisture and oxygen can be effectively prevented.

The first oxygen barrier layer 910 and the second oxygen barrier layer 920 can have a smaller thermal conductivity than the encapsulation substrate 700. The second oxygen barrier layer 920 can include a different material from the first oxygen barrier layer 910. For example, a thermal conductivity of the first oxygen barrier layer 910 can be smaller than a thermal conductivity of the second oxygen barrier layer 920. An upper surface of the second oxygen barrier layer 920 opposite to the device substrate 100 can be in direct contact with the encapsulation substrate 700. Thus, in the display apparatus according to another embodiment of the present disclosure, the heat generated by the operation of the driving circuit DC and the light-emitting device 300 in each pixel area PA can be quickly transferred to the encapsulation substrate 700 through the first oxygen barrier layer 910 and the second oxygen barrier layer 920. Therefore, in the display apparatus according to another embodiment of the present disclosure, the heat dissipation efficiency can be improved.

A surface of the second oxygen barrier layer 920 toward the second encapsulating layer 620 can have a greater average surface roughness than a surface of the second oxygen barrier layer 920 toward the encapsulation substrate 700. For example, a process of forming the second oxygen barrier layer 920 can include a step of forming a metal oxide layer on a surface of the encapsulation substrate 700 and a step of deoxidizing the metal oxide layer using hydrogen plasma. Thus, in the display apparatus according to another embodiment of the present disclosure, a contact area between the second encapsulating layer 620 and the second oxygen barrier layer 920 can be increased. That is, in the display apparatus according to another embodiment of the present disclosure, an adhesive force between the encapsulating adhesive layer 600 and the second oxygen barrier layer 920 can be increased. Therefore, in the display apparatus according to another embodiment of the present disclosure, the interface separation between the encapsulating adhesive layer 600 and the second oxygen barrier layer 920 due to the external impact can be prevented.

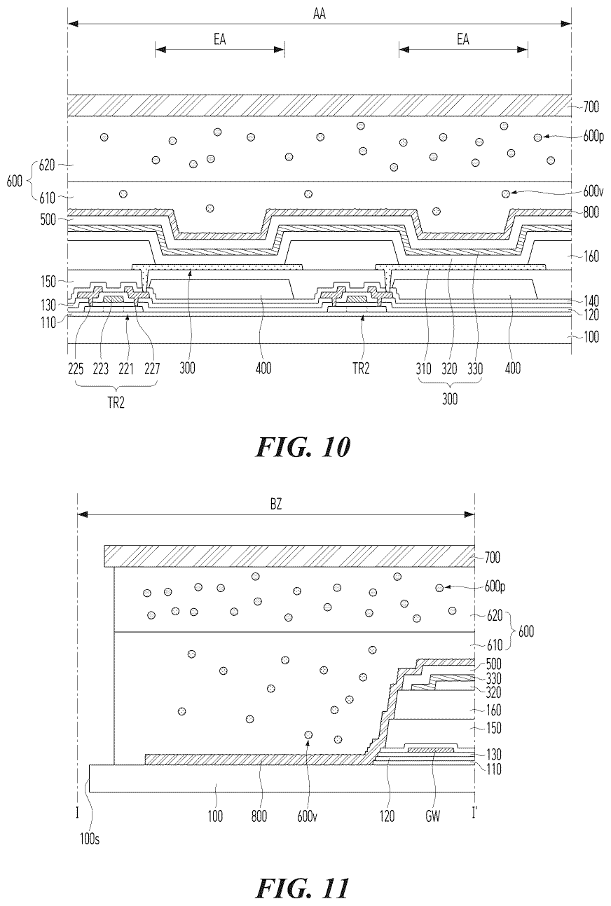

The display apparatus according to the embodiment of the present disclosure is described that only the plurality of moisture absorbing particles 600p is dispersed in the encapsulating adhesive layer 600. However, in the display apparatus according to another embodiment of the present disclosure, various types of particles can be dispersed in the encapsulating adhesive layer 600. For example, in the display apparatus according to another embodiment of the present disclosure, the encapsulating adhesive layer 600 can include the plurality of moisture absorbing particles 600p and a plurality of color-change particles 600v, as shown in FIGS. 10 and 11. Each of the color-change particles 600v can include a material that reacts with oxygen atoms and oxygen molecules to change color. For example, each of the color-change particles 600v can include leuco methylene blue (LMB) displaying a blue color by reacting with oxygen. The plurality of color-change particles 600v can be dispersed in the first encapsulating layer 610 and the second encapsulating layer 620. Thus, in the display apparatus according to another embodiment of the present disclosure, the penetration location of moisture and oxygen can be easily checked by the change in the color of the encapsulating adhesive layer 600. And, in the display apparatus according to another embodiment of the present disclosure, the degree of the penetration of moisture and oxygen can be easily checked by the change in the color of the encapsulating adhesive layer 600. Therefore, in the display apparatus according to another embodiment of the present disclosure, a region in which moisture and/or oxygen is penetrated can be quickly repaired, before the light-emitting devices 300 are damaged.

In the display apparatus according to another embodiment of the present disclosure, the oxygen barrier layer 800 can be covered by the encapsulating adhesive layer 600. For example, a side surface of the encapsulating adhesive layer 600 can be disposed between the side surface of the device substrate 100 and the side surface of the oxygen barrier layer 800. The encapsulating adhesive layer 600 can be in direct contact with the bezel area BZ of the device substrate 100 outside the oxygen barrier layer 800. Thus, in the display apparatus according to another embodiment of the present disclosure, the peeling of the encapsulating adhesive layer 600 and the oxygen barrier layer 800 due to the external impact can be effectively prevented. And, in the display apparatus according to another embodiment of the present disclosure, the damage of the oxygen barrier layer 800 due to the external impact can be prevented. Therefore, in the display apparatus according to another embodiment of the present disclosure, the damage of the light-emitting device 300 on each pixel area PA due to the penetration of the external moisture and oxygen can be effectively prevented. Further, in the display apparatus according to another embodiment of the present disclosure, the penetration path of the external moisture and oxygen can be easily checked. That is, in the display apparatus according to another embodiment of the present disclosure, a region in which the external moisture and/or oxygen is penetrated can be quickly repaired.

In the result, the display apparatus according to the embodiments of the present disclosure can comprise the capping insulating layer on the light-emitting device, the oxygen barrier layer on the capping insulating layer, the encapsulating adhesive layer on the oxygen barrier layer, and the encapsulation substrate on the encapsulating adhesive layer, wherein the oxygen barrier layer includes a metal that reacts with the oxygen faster than the encapsulation substrate. Thus, in the display apparatus according to the embodiments of the present disclosure, the penetration of the external moisture and oxygen that is not captured by the encapsulating adhesive layer can be blocked by the oxygen barrier layer. That is, in the display apparatus according to the embodiments of the present disclosure, the damage of the light-emitting device due to the external moisture and oxygen can be effectively prevented. Thereby, in the display apparatus according to the embodiments of the present disclosure, the efficiency and the lifespan of the light-emitting device can be improved.

And, in the display apparatus according to the embodiments of the present disclosure, the low power operation is possible and the power consumption can be reduced.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a device substrate having a display area and a bezel area;
a light-emitting device on the display area of the device substrate, the light-emitting device including an electrode;
a capping insulating layer on the electrode of the light-emitting device;
an encapsulating adhesive layer on the capping insulating layer, the encapsulating adhesive layer extending on the bezel area of the device substrate;
an encapsulation substrate on the encapsulating adhesive layer, the encapsulation substrate overlapping with the display area and the bezel area; and
an oxygen barrier layer disposed between the capping insulating layer and the encapsulating adhesive layer, the oxygen barrier layer including a metal, the oxygen barrier layer having a first surface and a second surface opposite to the first surface,
wherein the first surface of the oxygen barrier layer toward the encapsulating adhesive layer has an average surface roughness greater than the second surface of the oxygen barrier layer.

2. The display apparatus according to claim 1, wherein a thermal conductivity of the encapsulation substrate is greater than a thermal conductivity of the oxygen barrier layer.

3. The display apparatus according to claim 1, wherein the oxygen barrier layer includes a region in contact with the bezel area of the device substrate.

4. The display apparatus according to claim 3, wherein the encapsulating adhesive layer is in contact with the bezel area of the device substrate outside the oxygen barrier layer.

5. The display apparatus according to claim 1, wherein the encapsulating adhesive layer includes a plurality of moisture absorbing particles and a plurality of color-changing particles, and
wherein each of the plurality of color-changing particles includes a material that reacts with oxygen atoms and/or oxygen molecules to change color.

6. The display apparatus according to claim 1, wherein a thickness of the oxygen barrier layer overlapping with the bezel area is larger than a thickness of the oxygen barrier layer overlapping with the display area.

7. The display apparatus according to claim 1, wherein the oxygen barrier layer includes a first barrier region and a second barrier region having a higher transmittance than the first barrier region, and
wherein the second barrier region is disposed between the first barrier region and a side surface of the device substrate in a direction parallel to an upper surface of the device substrate.

8. The display apparatus according to claim 7, wherein the second barrier region of the oxygen barrier layer is made of metal oxide semiconductor.

9. A display apparatus, comprising:
a device substrate;
a light-emitting device on the device substrate, the light-emitting device having an electrode;
a capping insulating layer covering the electrode of the light-emitting device;
an encapsulating adhesive layer covering the light-emitting device and the capping insulating layer;
an encapsulation substrate on the encapsulating adhesive layer, the encapsulation substrate including a metal; and
a first oxygen barrier layer disposed between the capping insulating layer and the encapsulating adhesive layer,
wherein the first oxygen barrier layer includes a metal that oxidizes faster than the encapsulation substrate.

10. The display apparatus according to claim 9, wherein a side surface of the first oxygen barrier layer disposed close to a side surface of the device substrate is continuous with a side surface of the encapsulating adhesive layer disposed close to the side surface of the device substrate.

11. The display apparatus according to claim 9, further comprising a second oxygen barrier layer disposed between the encapsulating adhesive layer and the encapsulation substrate,
wherein the second oxygen barrier layer includes a metal that oxidizes faster than the encapsulation substrate.

12. The display apparatus according to claim 11, wherein a thermal conductivity of the second oxygen barrier layer is smaller than a thermal conductivity of the encapsulation substrate.

13. The display apparatus according to claim 11, wherein the second oxygen barrier layer includes a different material from the first oxygen barrier layer.

14. The display apparatus according to claim 13, wherein a thermal conductivity of the first oxygen barrier layer is smaller than a thermal conductivity of the second oxygen barrier layer.

15. The display apparatus according to claim 9, wherein the first oxygen barrier layer includes a first barrier region and a second barrier region displaying a different color from the first barrier region, and
wherein the second barrier region is disposed between the first barrier region and the capping insulation layer.

16. The display apparatus according to claim 11, wherein the first oxygen barrier layer or the second oxygen barrier layer is formed by a deoxidization process using hydrogen plasma.

17. The display apparatus according to claim 11, wherein a surface of the second oxygen barrier layer toward the encapsulating adhesive layer has a greater average surface roughness than a surface of the second oxygen barrier layer toward the encapsulation substrate.

18. The display apparatus according to claim 7, wherein the second barrier region has a greater thickness near a side surface of the device substrate than at a central portion of the display area.
